(19) United States
(12) Patent Application Publication
(10) Pub. No.: US 2025/0120221 A1
(43) Pub. Date: Apr. 10, 2025

(54) LIGHT-EMITTING DEVICE AND MANUFACTURING METHOD THEREOF

(71) Applicant: ENKRIS SEMICONDUCTOR, INC., Suzhou, Jiangsu (CN)

(72) Inventor: Kai CHENG, Suzhou, Jiangsu (CN)

(21) Appl. No.: 18/836,025

(22) PCT Filed: Jun. 30, 2022
(86) PCT No.: PCT/CN2022/103181

§ 371 Date: Aug. 6, 2024

(51) Int. Cl. H10H 20/819; H10H 20/01; H10H 20/814; H10H 20/825

(52) U.S. Cl. CPC H10H 20/819; H10H 20/0137; H10H 20/814; H10H 20/825

(57) ABSTRACT

The present application provides a light-emitting device and a manufacturing method thereof. The light-emitting device includes: a base, a first mask layer, a first epitaxial layer, and a light-emitting structure; the first mask layer is arranged on the base and has a first window exposing the base, the first window includes an opening end, where the area of an orthographic projection of the opening end on a plane of the base is smaller than an area of an orthographic projection of the first window on the plane of the base; the first epitaxial layer is epitaxially grown from the base to fill up the first window; the light-emitting structure is arranged on the first epitaxial layer and the first mask layer. Inward sidewalls of the first window are utilized, so that the dislocation of the epitaxially grown GaN-based material terminates at the sidewalls of the first window.

### CROSS-REFERENCE TO RELATED APPLICATIONS

This application is a national stage of international PCT Application No. PCT/CN2022/103181 filed on Jun. 30, 2022, the entire contents of which are incorporated herein by reference.

### TECHNICAL FIELD

The present disclosure relates to the field of semiconductor technologies, and in particular, to a light-emitting device and a manufacturing method thereof.

### BACKGROUND

Gallium nitride (GaN) is a third-generation new semiconductor material following the first and second generation semiconductor materials such as Si and GaAs, and as a wide bandgap semiconductor material, it has many advantages, such as high saturation drift speed, large breakdown voltage, excellent carrier transport performance, and capabilities to form AlGaN, InGaN ternary alloys, and AlInGaN quaternary alloys, etc., and GaN-based PN junctions are easy to be manufactured. In view of this, in recent years, GaN-based materials and light-emitting devices have been extensively and deeply studied, and Metal-organic Chemical Vapor Deposition (MOCVD) technology has become more and more mature for growing the GaN-based materials. In terms of the light-emitting device research, remarkable achievements and great progress have been made in the research of optoelectronic devices such as GaN-based LEDs (light-emitting diodes) and LDs (laser diodes), as well as microelectronic devices such as GaN-based HEMTs (High Electron Mobility Transistors).

With the gradual deepening of the application of the GaN-based materials in display devices, the requirements for the dislocation density of the GaN-based materials in terminal products have further increased. According to the traditional mode using mainstream MOCVD epitaxial equipment, the areal density of dislocations for the GaN-based materials epitaxially grown on the aluminum oxide (Al₂O₃) substrate of the mainstream GaN-based epitaxial base is about 1˜3E8/cm\hat{ }3. In order to manufacture GaN-based light-emitting devices with the higher light-emitting efficiency, the dislocation density of the GaN-based materials must be further reduced.

In view of this, it is necessary to provide a new light-emitting device and a manufacturing method thereof to meet the above requirements.

### SUMMARY

The purpose of the present disclosure is to provide a light-emitting device and a manufacturing method thereof, which reduces the dislocation density of a GaN-based material and improves the light-emitting efficiency of the light-emitting device.

To achieve the above purpose, the first aspect of embodiments of the present disclosure provides a light-emitting device, including:
a base;
a first mask layer on the base, where the first mask layer includes a first window exposing the base, the first window includes an opening end, and an area of an orthographic projection of the opening end on a plane of the base is smaller than an area of an orthographic projection of the first window on the plane of the base;
a first epitaxial layer, epitaxially grown from the base to fill up the first window; and
a light-emitting structure, arranged on the first epitaxial layer and the first mask layer.

Optionally, the light-emitting structure includes:
a second epitaxial layer, epitaxially grown on the first epitaxial layer and the first mask layer from the first epitaxial layer;
an active layer on the second epitaxial layer; and
a third epitaxial layer on the active layer.

Optionally, the first mask layer is a multi-layer structure including alternately arranged first sublayers and second sublayers, and the first sublayers and the second sublayers have different refractive indexes to form a Bragg reflector enabling light emitted by the light-emitting structure to exit in a direction perpendicular to the plane of the base and away from the base.

Optionally, the first mask layer includes a metal reflecting layer, an orthographic projection of the light-emitting structure on the plane of the base falls within an orthographic projection of the metal reflecting layer on the plane of the base, and the metal reflecting layer enables light emitted by the light-emitting structure to exit in a direction perpendicular to the plane of the base and away from the base.

Optionally, there are groups of first windows, and in each of the groups, the group includes a plurality of first windows, the opening end of each first window in the group varies in area size and/or spacing between opening ends of each pair of adjacent first windows in the group varies, to enable the light-emitting structure corresponding to each of the opening ends to vary in light-emitting wavelength.

Optionally, the light-emitting device further includes:
a second mask layer on the first mask layer, where the second mask layer includes a second window exposing the first mask layer, the second window is connected with the first window, and at least the second epitaxial layer and the active layer are arranged in the second window.

Optionally, there are several groups of second windows, and in each of the groups, the group comprises a plurality of the second windows, the plurality of the second windows vary in horizontal-sectional area size and/or spacing between each pair of adjacent second windows of the plurality of second windows varies, to enable the light-emitting structure corresponding to each of the plurality of second windows to vary in light-emitting wavelength.

Optionally, a composition of the active layer is InGaN, and in each of the groups, each of the plurality of second windows varies in horizontal-sectional area size and/or the spacing between each pair of adjacent second windows of the plurality of second windows varies, to enable a component content of In in a corresponding InGaN in the plurality of second window to vary.

Optionally, the first window further includes a bottom wall end on a surface of the base, and the orthographic projection of the opening end on the plane of the base is at least partially staggered from the bottom wall end.

Optionally, the orthographic projection of the opening end on the plane of the base is completely outside from the bottom wall end.

Optionally, the first window is a slanted columnar window.

Optionally, in a direction from the base to the opening end, a horizontal-sectional areas of the first window first increase and then decrease; in a direction from the base to the opening end, the horizontal-sectional areas of the first window gradually decrease; or in a direction from the base to the opening end, the horizontal-sectional areas of the first window are equal in size.

Optionally, in a direction from the base to the opening end, a line connecting centers of horizontal sections of the first window is a straight line, a polyline, or a curve.

The second aspect of embodiments of the present disclosure provides a manufacturing method of a light-emitting device, including:
providing a base, forming a first mask layer on the base, and in the first mask layer, forming first window exposing the base, where the first window includes an opening end, to enable an area of an orthographic projection of the opening end on a plane of the base to be smaller than an area of an orthographic projection of the first window on the plane of the base; and
performing an epitaxial growth process on the base to sequentially form a first epitaxial layer and a light-emitting structure by using the first mask layer as a mask, where the first epitaxial layer is epitaxially grown from the base to fill the first window, and the light-emitting structure is epitaxially grown on the first epitaxial layer and the first mask layer.

Optionally, the light-emitting structure includes:
a second epitaxial layer, epitaxially grown on the first epitaxial layer and the first mask layer from the first epitaxial layer;
an active layer on the second epitaxial layer; and
a third epitaxial layer on the active layer.

Optionally, a method of forming the first mask layer includes: alternately depositing first sublayers and second sublayers to form a multi-layer structure;
or includes:
depositing a first mask sublayer;
forming a metal reflecting layer on the first mask sublayer, to enable an orthographic projection of a predetermined region of the light-emitting structure on the plane of the base to fall within an orthographic projection of the metal reflecting layer on the plane of the base; and
forming a second mask sublayer on the metal reflecting layer and the first mask sublayer, where the first mask layer is formed by the first mask sublayer and the second mask sublayer.

Optionally, before the step of forming the first epitaxial layer and the light-emitting structure, the manufacturing method of the light-emitting device further includes:
forming a second mask layer on the first mask layer, and in the second mask layer, forming a second window exposing the first mask layer, where the second window is connected with the first window; and
performing an epitaxial growth process on the base by using the first mask layer and the second mask layer as masks, where at least the second epitaxial layer and the active layer of the light-emitting structure are epitaxially grown in the second window.

Optionally, a composition of the active layer is InGaN, there are several groups of second windows, and in each of the groups, the group comprises a plurality of the second windows, each of the plurality of second windows varies in horizontal-sectional area size and/or spacing between each pair of adjacent second windows varies, to enable a component content of In in a corresponding InGaN epitaxially grown in the second window to vary.

### BRIEF DESCRIPTION OF DRAWINGS

FIG. 1 is a cross-sectional structural diagram of a light-emitting device according to the first embodiment of the present disclosure;

FIG. 2 is a cross-sectional structural diagram of the base and the first mask layer of the light-emitting device in FIG. 1;

FIG. 3 is a flow chart of a manufacturing method of the light-emitting device in FIG. 1;

FIG. 4 is a cross-sectional structural diagram of a light-emitting device according to the second embodiment of the present disclosure;

FIG. 5 is a cross-sectional structural diagram of the base and the first mask layer of the light-emitting device in FIG. 4;

FIG. 6 is a cross-sectional structural diagram of a light-emitting device according to the third embodiment of the present disclosure;

FIG. 7 is a cross-sectional structural diagram of the base and the first mask layer of the light-emitting device in FIG. 6;

FIG. 8 is a cross-sectional structural diagram of a light-emitting device according to the fourth embodiment of the present disclosure;

FIG. 9 is a cross-sectional view of the light-emitting device in FIG. 8 along the line AA;

FIG. 10 is a cross-sectional structural diagram of the base and the first mask layer of the light-emitting device in FIG. 9;

FIG. 11 is a cross-sectional structural diagram of a light-emitting device according to the fifth embodiment of the present disclosure;

FIG. 12 is a cross-sectional structural diagram of the base, the first mask layer, and the second mask layer of the light-emitting device in FIG. 11;

FIG. 13 is a flow chart of a manufacturing method of the light-emitting device in FIG. 11;

FIG. 14 is a top structural view of a light-emitting device according to the sixth embodiment of the present disclosure;

FIG. 15 is a cross-sectional view of the light-emitting device in FIG. 14 along the line BB;

FIG. 16 is a cross-sectional structural diagram of the base, the first mask layer, and the second mask layer of the light-emitting device in FIG. 14;

FIG. 17 is a cross-sectional structural diagram of the base and the first mask layer of the light-emitting device according to the seventh embodiment of the present disclosure;

FIG. 18 is a cross-sectional structural diagram of the base and the first mask layer of the light-emitting device according to the eighth embodiment of the present disclosure;

FIG. 19 is a cross-sectional structural diagram of the base and the first mask layer of the light-emitting device according to the ninth embodiment of the present disclosure;

FIG. 20 is a cross-sectional structural diagram of the base and the first mask layer of the light-emitting device according to the tenth embodiment of the present disclosure;

FIG. 21 is a cross-sectional structural diagram of the base and the first mask layer of the light-emitting device according to the eleventh embodiment of the present disclosure;

FIGS. 22 and 23 are cross-sectional structural diagrams of a light-emitting device according to the twelfth embodiment of the present disclosure; and

FIG. 24 is a cross-sectional structural diagram of a light-emitting device according to the thirteenth embodiment of the present disclosure.

To facilitate the understanding of the present disclosure, all reference signs present in the present disclosure are listed below:

| | |
|---|---|
| Light-emitting devices | Base 10 |
| 1, 2, 3, 4, 5, 6, and 8 | |
| Semiconductor substrate 100 | Transition layer 101 |
| First mask layer 11 | First window 110 |
| Opening end 110a | Bottom wall end 110b |
| Slanted columnar window 111 | First sidewall 11a |
| Second sidewall 11b | First angle α |
| Second angle β | Second mask layer 12 |
| Second window 120 | First sublayer 112 |
| Second sublayer 113 | Metal reflecting layer 114 |
| First thickness layer 115 | Second thickness layer 116 |
| First epitaxial layer 13 | Light-emitting structure 14 |
| Second epitaxial layer 141 | Active layer 142 |
| Third epitaxial layer 143 | First mask sublayer 112′ |
| Second mask sublayer 113′ | First electrode 15 |
| Second electrode 16 | Insulating material layer 161 |

### DETAILED DESCRIPTION

In order to make the above-mentioned objects, features and advantages of the present disclosure more obvious and understandable, embodiments of the present disclosure will be described in detail below with reference to the accompanying drawings.

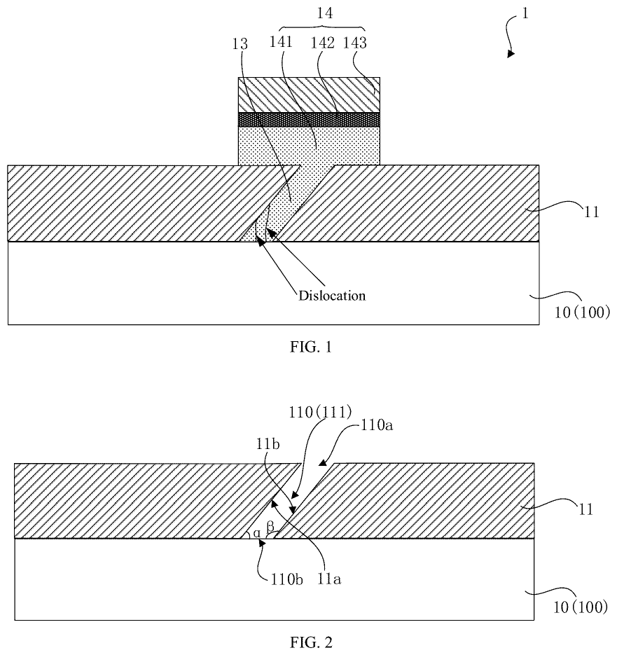

FIG. 1 is a cross-sectional structural diagram of a light-emitting device according to the first embodiment of the present disclosure, and FIG. 2 is a cross-sectional structural diagram of the base and the first mask layer of the light-emitting device in FIG. 1.

Referring to FIGS. 1 and 2, the light-emitting device 1 includes:
a base 10;
a first mask layer 11 on the base 10, where the first mask layer 11 includes a first window 110 exposing the base 10 and including an opening end 110a, and the area of the orthographic projection of the opening end 110a on the plane of the base 10 is smaller than the area of the orthographic projection of the first window 110 on the plane of the base 10;
a first epitaxial layer 13, epitaxially grown from the base 10 to fill up the first window 110; and
a light-emitting structure 14, arranged on the first epitaxial layer 13 and the first mask layer 11.

In this embodiment, the base 10 is a multi-layer structure, including, for example, a semiconductor substrate 100 and a nucleation layer (not illustrated) on the semiconductor substrate 100. The semiconductor substrate 100 may be made of at least one of sapphire, silicon carbide, and monocrystalline silicon, and the nucleation layer may be made of AlN.

In this embodiment, the semiconductor substrate 100 refers to a substrate for epitaxial growth of a semiconductor material, and does not limit its material to a semiconductor.

In other embodiments, the base 10 may be a single-layer structure, for example, the base 10 may be a semiconductor substrate 100. The semiconductor substrate 100 may be made of silicon carbide, gallium nitride, etc.

In this embodiment, the first mask layer 11 is a single-layer structure. The first mask layer 11 may be made of one of silicon dioxide and silicon nitride.

In this embodiment, there is one first window 110, and the first window 110 is a slanted columnar window 111. A vertical section of the slanted columnar window 111 is a slanted parallelogram, where the vertical section refers to a section perpendicular to the plane of the base 10. A horizontal section of the slanted columnar window 111 is a rectangle, where the horizontal section refers to a section parallel to the plane of the base 10.

The first mask layer 11 includes the first sidewall 11a and the second sidewall 11b which are opposite to each other, the angle between the first sidewall 11a and the base 10 exposed by the slanted columnar window 111 is the first angle α, which is an acute angle; the angle between the second sidewall 11b and the base 10 exposed by the slanted columnar window 111 is the second angle β, which is an obtuse angle; and the first angle α is equal to the supplementary angle of the second angle β.

The slanted columnar window 111 further includes a bottom wall end 110b on the surface of the base 10, and the orthographic projection of the opening end 110a on the plane of the base 10 is completely outside the bottom wall end 110b, the advantage of which is that: when the dislocation of the material for epitaxial growth in the slanted columnar window 111 is along or at an angle with the thickness direction of the first mask layer 11, the smaller the angle between the sidewall of the slanted columnar window 111 and the direction of the plane of the base 10, the larger the area of the sidewall for terminating the dislocation extension, and thus the better the termination effect. For example, when the epitaxially grown first epitaxial layer 13 is made of a GaN material, the dislocations of the GaN material are mainly threading (linear) dislocations in the crystal direction, i.e., the threading dislocations extending along the thickness direction of the first mask layer 11, at this time, the smaller the first angle α between the first sidewall 11a and the base 10 exposed by the slanted columnar window 111, the larger the area of the first sidewall 11a that can terminate the dislocation extension, and thus, the better the termination effect. Therefore, the dislocation density in the first epitaxial layer 13 and the light-emitting structure 14 that continues epitaxial growth on the first mask layer 11 is lower.

In other embodiments, the orthographic projection of the opening end 110a on the plane of the base 10 may also be at least partially staggered from the bottom wall end 110b.

In other embodiments, the horizontal section of the first window 110 may be a triangle, a hexagon, a circle, or other shapes.

In this embodiment, the light-emitting structure 14 includes:
a second epitaxial layer 141, epitaxially grown on the first epitaxial layer 13 and the first mask layer 11 from the first epitaxial layer 13;
an active layer 142 on the second epitaxial layer 141; and
a third epitaxial layer 143 on the active layer 142.

The second epitaxial layer 141 and the first epitaxial layer 13 are made of the same material, which may be GaN. The active layer 142 may be made of at least one of AlGaN, InGaN, and AlInGaN. The third epitaxial layer 143 may be made of GaN. The conductivity type of the second epitaxial layer 141 is opposite to the conductivity type of the third epitaxial layer 143, for example, one is P-type doping and the other is N-type doping.

In other embodiments, the light-emitting structure 14 may also be other structures, which is not limited in this embodiment.

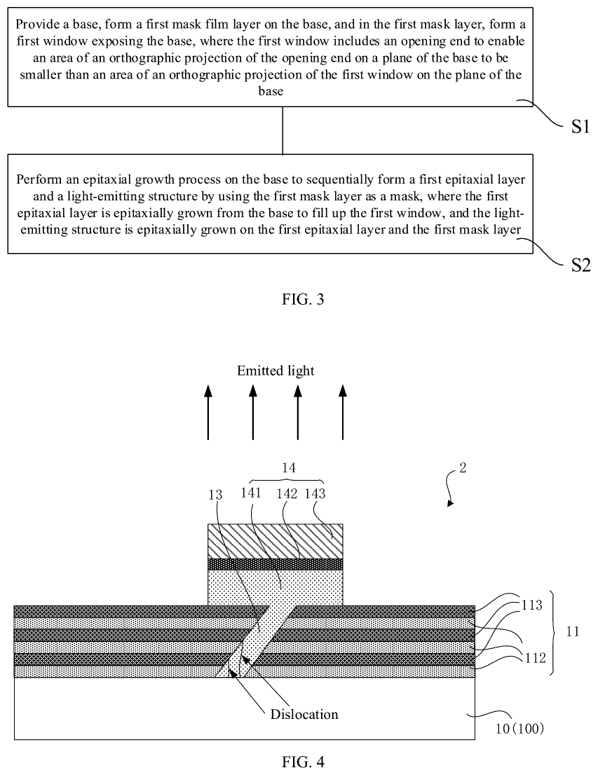

The first embodiment of the present disclosure further provides a manufacturing method of a light-emitting device in FIG. 1. FIG. 3 is a flow chart of the manufacturing method.

First, referring to FIG. 2 and step S1 in FIG. 3, providing a base 10, forming a first mask layer 11 on the base 10, and in the first mask layer 11, forming a first window 110 exposing the base 10 and including an opening end 110a, to enable the area of the orthographic projection of the opening end 110a on the plane of the base 10 to be smaller than the area of the orthographic projection of the first window 110 on the plane of the base 10.

In this embodiment, the base 10 is a multi-layer structure, including, for example, a semiconductor substrate 100 and a nucleation layer (not illustrated) on the semiconductor substrate 100. The semiconductor substrate 100 may be made of at least one of sapphire, silicon carbide, and single crystal silicon, and the nucleation layer may be made of AlN.

In other embodiments, the base 10 may be a single-layer structure, for example, the base 10 may be a semiconductor substrate 100. The semiconductor substrate 100 may be made of silicon carbide, gallium nitride, etc.

The first mask layer 11 may be made of one of silicon dioxide and silicon nitride, and correspondingly the first mask layer 11 is formed by adopting physical vapor deposition or chemical vapor deposition. In this embodiment, the first mask layer 11 is a single-layer structure. The single-layer structure may be formed in one process.

In this embodiment, when the first window 110 is formed, there is one first window 110, and the first window 110 is a slanted columnar window 111. The slanted columnar window 111 may be formed by controlling the etching gas type and flow rate or controlling the plasma direction during dry etching.

Subsequently, referring to FIGS. 1 and 2, and step S2 in FIG. 3, performing an epitaxial growth process on the base 10 to sequentially form the first epitaxial layer 13 and the light-emitting structure 14 by using the first mask layer 11 as a mask, where the first epitaxial layer 13 is epitaxially grown from the base 10 to fill up the first window 110, and the light-emitting structure 14 is epitaxially grown on the first epitaxial layer 13 and the first mask layer 11.

In this embodiment, the light-emitting structure 14 includes:
a second epitaxial layer 141, epitaxially grown on the first epitaxial layer 13 and the first mask layer 11 from the first epitaxial layer 13;
an active layer 142 on the second epitaxial layer 141; and
a third epitaxial layer 143 on the active layer 142.

The formation processes of the first epitaxial layer 13, the second epitaxial layer 141, the active layer 142, and the third epitaxial layer 143 may include: atomic layer deposition (ALD), chemical vapor deposition (CVD), molecular beam epitaxy (MBE), plasma enhanced chemical vapor deposition (PECVD), low pressure chemical vapor deposition (LPCVD), metal-organic chemical vapor deposition (MOCVD), or a combination thereof. The doped ions in the second epitaxial layer 141 and the third epitaxial layer 143 may be doped in-situ.

When the base 10 is a multi-layer structure, including, for example, a semiconductor substrate 100 and a nucleation layer located on the semiconductor substrate 100, the first epitaxial layer 13 and the second epitaxial layer 141 are heteroepitaxial. When the base 10 is a single-layer structure, for example, when the base 10 is a silicon carbide semiconductor substrate 100, the first epitaxial layer 13 and the second epitaxial layer 141 are homoepitaxial.

The first epitaxial layer 13 and the second epitaxial layer 141 are made of the same material, and may be GaN-based materials, e.g., GaN. The dislocation in the GaN-based material is along or at an angle with the thickness direction of the first mask layer 11. Since there is an angle α between the sidewall 11a of the slanted columnar window 111 and the direction of the plane of the base 10, the dislocations of the first epitaxial layer 13 can be terminated when extending to the first sidewall 11a, thereby reducing the dislocation density in the light-emitting structure 14.

FIG. 4 is a cross-sectional structural diagram of a light-emitting device according to the second embodiment of the present disclosure, and FIG. 5 is a cross-sectional structural diagram of the base and the first mask layer of the light-emitting device in FIG. 4.

Referring to FIGS. 4 and 5, the difference between the light-emitting device 2 in the second embodiment and the light-emitting device 1 in the first embodiment lies in that, the first mask layer 11 is a multi-layer structure including alternately arranged first sublayers 112 and second sublayers 113, and the first sublayers 112 and the second sublayers 113 have different refractive indexes to form a Bragg reflector enabling light emitted by the light-emitting structure 14 to exit in a direction perpendicular to the plane of the base 10 and away from the base 10.

The first sublayer 112 may be made of one of silicon dioxide and silicon nitride, and the second sublayer 113 may be made of the other of silicon dioxide and silicon nitride.

The alternately arranged first sublayers 112 and second sublayers 113 may form a total reflection structure, so that the light emitted by the light-emitting structure 14 is completely reflected in the direction toward the base 10. Further, the luminance of the light-emitting device 2 is improved.

In addition to the above difference, other structures of the light-emitting device 2 in the second embodiment may refer to the corresponding structures of the light-emitting device 1 in the first embodiment.

The difference between the manufacturing method of the light-emitting device 2 in the second embodiment and the manufacturing method of the light-emitting device 1 in the first embodiment lies in that, the formation method of the first mask layer 11 includes: alternately depositing first sublayers 112 and second sublayers 113 to form a multi-layer structure.

In addition to the above difference, other process steps of the light-emitting device 2 in the second embodiment may refer to the corresponding process steps of the light-emitting device 1 in the first embodiment.

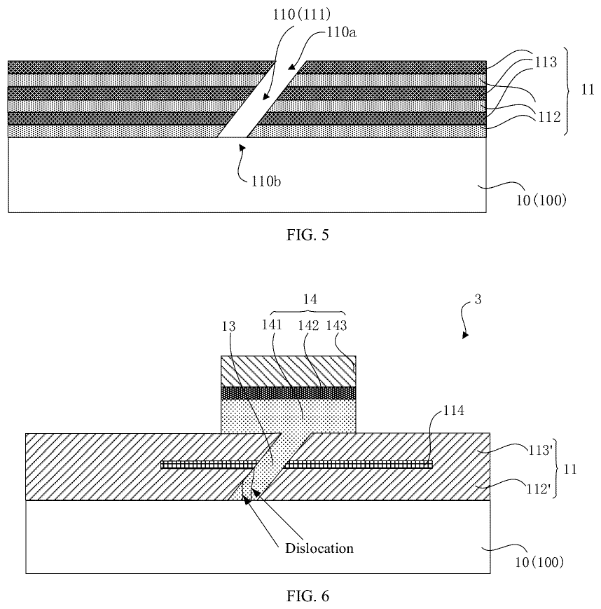

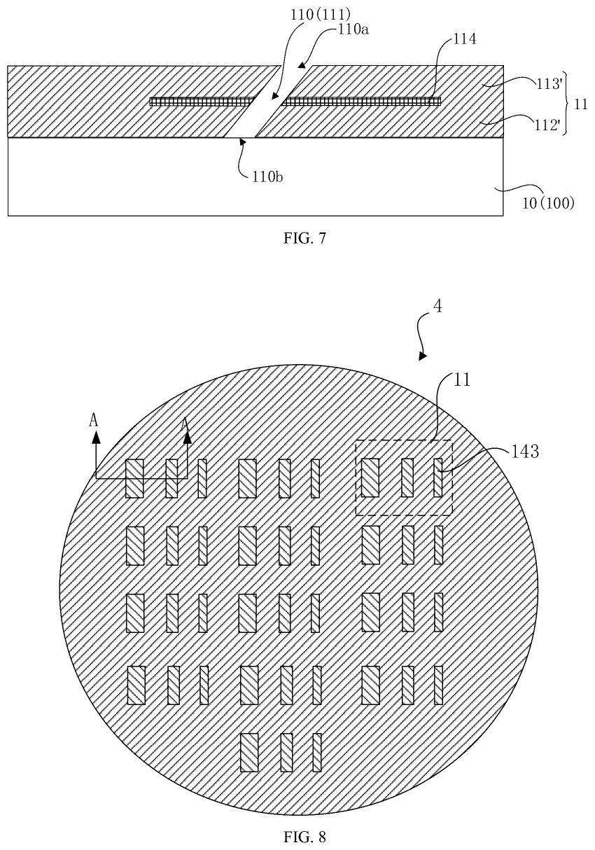

FIG. 6 is a cross-sectional structural diagram of a light-emitting device according to the third embodiment of the present disclosure, and FIG. 7 is a cross-sectional structural diagram of the base and the first mask layer of the light-emitting device in FIG. 6.

Referring to FIGS. 6 and 7, the difference between the light-emitting device 3 in the third embodiment and the light-emitting device 1 in the first embodiment lies in that, the first mask layer 11 includes a metal reflecting layer 114, the orthographic projection of the light-emitting structure 14 on the plane of the base 10 falls within the orthographic projection of the metal reflecting layer 114 on the plane of the base 10, and the metal reflecting layer 114 enables the light emitted by the light-emitting structure 14 to exit in a direction perpendicular to the plane of the base 10 and away from the base 10.

The metal reflecting layer 114 may be made of silver.

The metal reflecting layer 114 in this embodiment may improve the luminance of the light-emitting device 3.

In addition to the above difference, other structures of the light-emitting device 3 in the third embodiment may refer to the corresponding structures of the light-emitting device 1 in the first embodiment.

Referring to FIG. 7, the difference between the manufacturing method of the light-emitting device 3 in the third embodiment and the manufacturing method of the light-emitting device 1 in the first embodiment lies in that, a formation method of the first mask layer 11 includes:
step S11, depositing a first mask sublayer 112′;
step S12, forming a metal reflecting layer 114 on the first mask sublayer 112′, to enable the orthographic projection of a predetermined region of the light-emitting structure 14 on the plane of the base 10 to fall within the orthographic projection of the metal reflecting layer 114 on the plane of the base 10; and
step S13, forming a second mask sublayer 113′ on the metal reflecting layer 114 and the first mask sublayer 112′, where the first mask layer 11 is formed by the first mask sublayer 112′ and the second mask sublayer 113′.

The metal reflecting layer 114 may be formed by performing a patterning process on a metal material layer. The patterning process may include dry etching or wet etching. The first mask sublayer 112′, the metal material layer, and the second mask sublayer 113′ may be formed on the entire surface by physical vapor deposition or vapor deposition.

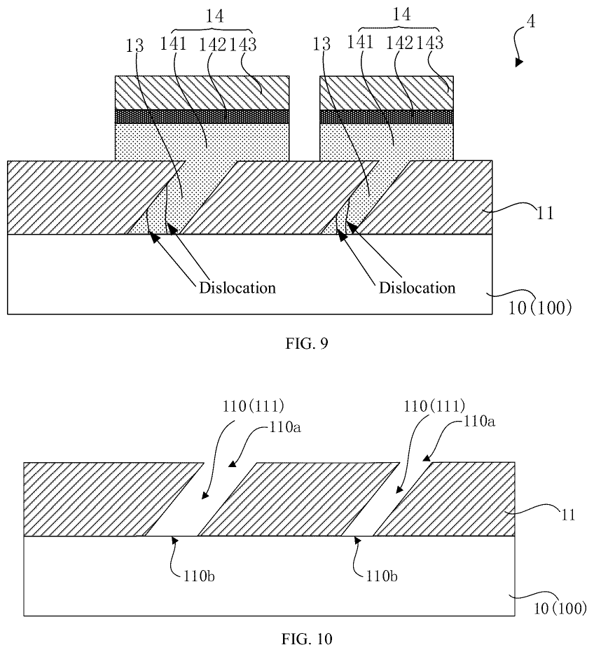

FIG. 8 is a top structural view of a light-emitting device according to the fourth embodiment of the present disclosure. FIG. 9 is a cross-sectional view of the light-emitting device in FIG. 8 along line AA, and FIG. 10 is a cross-sectional structural diagram of the base and the first mask layer of the light-emitting device in FIG. 9.

Referring to FIGS. 8 to 10, the difference between the light-emitting device 4 and the manufacturing method thereof in the fourth embodiment, and the light-emitting devices 1, 2, and 3 and the manufacturing methods thereof in the first, second, and third embodiments lies in that, the light-emitting device 4 includes several groups of first windows 110, and in each group, there are a plurality of first windows 110, the opening end 110a of each first window 110 in the group varies in area size, so that the light-emitting structure 14 corresponding to each opening end 110a emits light at different wavelengths.

For example, the smaller the area of the opening end 110a of the first window 110 means that the smaller the area of the upper surface of the first epitaxial layer 13, the smaller the proportion of the upper surface area of the first epitaxial layer 13 per unit area of the upper surface of the first mask layer 11, i.e., the smaller the proportion of the hole on the upper surface of the first epitaxial layer 13. The smaller the proportion of the hole on the upper surface of the first epitaxial layer 13, the faster the growth rate of the basic material GaN of the active layer 142 above the upper surface of the first epitaxial layer 13, the doping of the In element has better selectivity, and the greater the incorporation rate of the In element than the incorporation rate of the Ga element. Therefore, the smaller the proportion of the hole on the upper surface of the first epitaxial layer 13, the higher the component content of In element in InGaN in the active layer 142, and the longer the light-emitting wavelength of the light-emitting structure 14. The larger the area of the opening end 110a of the first window 110, the lower the component content of the In element in InGaN in the active layer 142, and the shorter the light-emitting wavelength of the light-emitting structure 14.

In other embodiments, the spacing between the opening ends 110a of each pair of adjacent first windows 110 may also be controlled to vary, so that the light-emitting structure 14 corresponding to each opening end 110a varies in light-emitting wavelength, and the principle is described below.

The greater the spacing between the opening ends 110a of adjacent first windows 110 means that the smaller the proportion of the upper surface area of the first epitaxial layer 13 in the unit area of the upper surface of the first mask layer 11, i.e., the smaller the proportion of the holes on the upper surface of the first epitaxial layer 13, the higher the component content of In in InGaN in the active layer 142 above the upper surface of the first epitaxial layer 13, and the longer the light-emitting wavelength of the light-emitting structure 14. The smaller the spacing between the opening ends 110a of adjacent first windows 110, the lower the component content of In in InGaN in the active layer 142, and the shorter the light-emitting wavelength of the light-emitting structure 14.

Furthermore, in some embodiments, the arrangement that the opening end 110a of each first window 110 in the group varies in area size and the arrangement that the spacing between the opening ends 110a of each pair of adjacent first windows 110 varies may be used in combination.

In addition to the above difference, other structures and process steps of the light-emitting device 4 in the fourth embodiment may refer to the corresponding structures and process steps of the light-emitting devices 1, 2, and 3 in the first, second, and third embodiments.

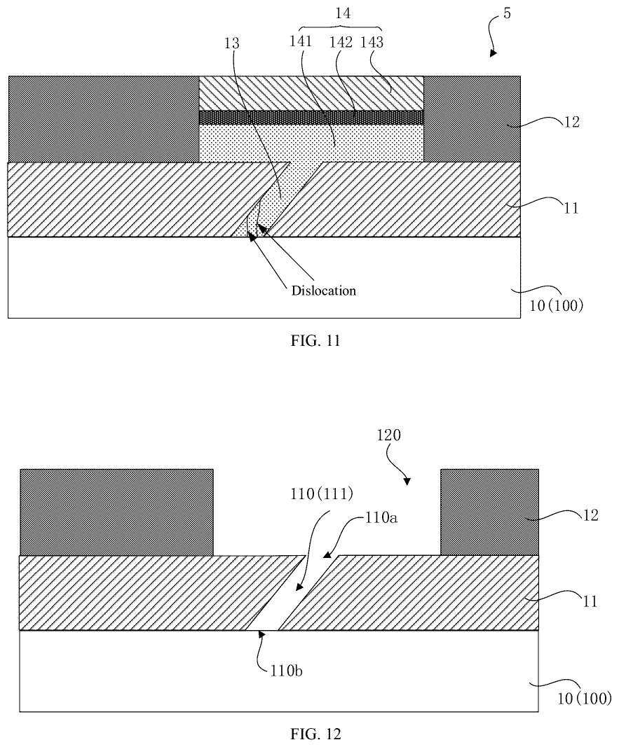

FIG. 11 is a cross-sectional structural diagram of a light-emitting device according to the fifth embodiment of the present disclosure, and FIG. 12 is a cross-sectional structural diagram of the base, the first mask layer, and the second mask layer of the light-emitting device in FIG. 11.

Referring to FIGS. 11 and 12, the difference between the light-emitting device 5 in the fifth embodiment and the light-emitting devices 1, 2, and 3 in the first, second, and third embodiments lies in that, the light-emitting device 5 further includes a second mask layer 12 on the first mask layer 11, where the second mask layer 12 has a second window 120 exposing the first mask layer 11 and connected with the first window 110, and at least the second epitaxial layer 141 and the active layer 142 are arranged in the second window 120.

The third epitaxial layer 143 may be entirely arranged in the second window 120, or may be partially arranged in the second window 120 and partially arranged outside the second window 120.

In this embodiment, the horizontal-sectional area of the second window 120 is greater than the area of the opening end 110a of the first window 110. In other embodiments, the horizontal-sectional area of the second window 120 may be smaller than or equal to the area of the opening end 110a of the first window 110.

In other embodiments, one second window 120 may be connected with two or more first windows 110. The horizontal-sectional shape of the second window 120 and that of the first window 110 may be the same or different. The horizontal section(s) of the second window 120 and/or the first window 110 may be a triangle, a hexagon, a circle, or other shapes.

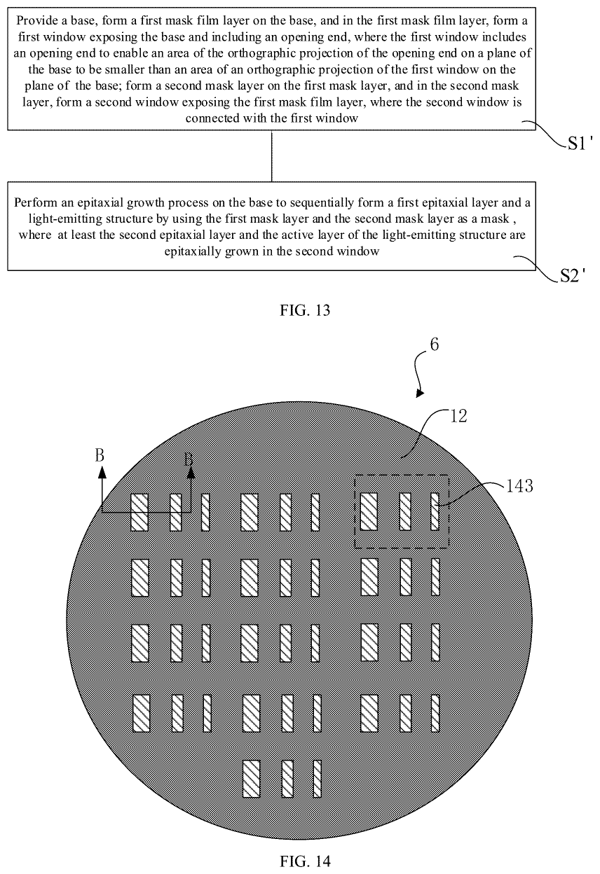

FIG. 13 is a flow chart of a manufacturing method of the light-emitting device in FIG. 11. Referring to FIGS. 13 and 3, the difference between the manufacturing method of the light-emitting device 5 in the fifth embodiment and the manufacturing methods of the light-emitting devices 1, 2, and 3 in the first, second, and third embodiments lies in that:
step S1′ after forming the first window 110 in the first mask layer 11 in step S1, the following is further performed: forming a second mask layer 12 on the first mask layer 11, and in the second mask layer 12, forming a second window 120 exposing the first mask layer 11 and connected with the first window 110; and
step S2′ the first mask layer 11 and the second mask layer 12 are used as masks to perform the epitaxial growth process on the base 10, where at least the second epitaxial layer 141 and the active layer 142 of the light-emitting structure 14 are epitaxially grown in the second window 120.

Compared with the manufacturing methods of the light-emitting devices 1, 2, and 3 in the first, second, and third embodiments, the light-emitting device 5 in this embodiment defines the region of the light-emitting structure 14 by using the second window 120 of the second mask layer 12.

In this embodiment, the second mask layer 12 is a single-layer structure. The material of the second mask layer 12 is different from that of the first mask layer 11, which may be one of silicon dioxide and silicon nitride, and the second mask layer 12 is formed by using physical vapor deposition or chemical vapor deposition. The material of the second mask layer 12 is different from that of the first mask layer 11, and a gas with a larger etching selectivity ratio between the second mask layer 12 and the first mask layer 11 may be selected as the etching gas for etching the second window 120, so that the first mask layer 11 is used for detecting the etching endpoint.

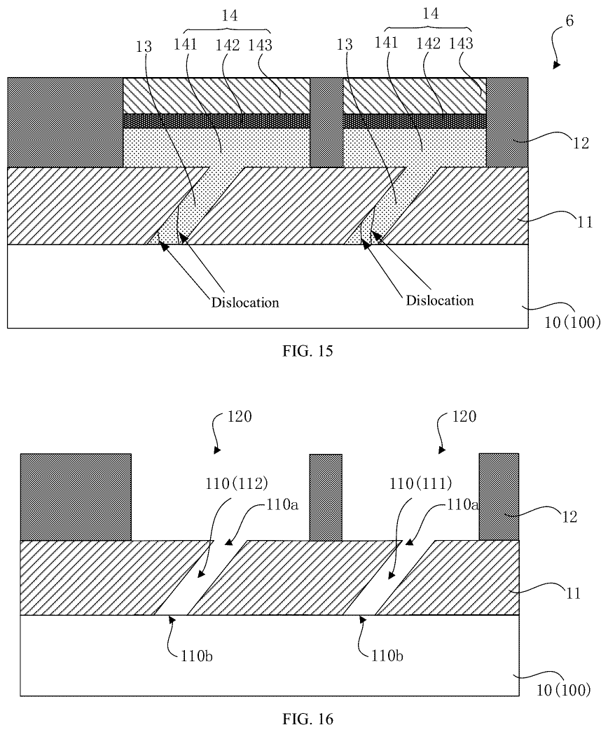

FIG. 14 is a top structural view of a light-emitting device according to the sixth embodiment of the present disclosure. FIG. 15 is a cross-sectional view of the light-emitting device in FIG. 14 along line BB, and FIG. 16 is a cross-sectional structural diagram of the base, the first mask layer, and the second mask layer of the light-emitting device in FIG. 14.

Referring to FIGS. 14 to 16, the difference between the light-emitting device 6 in the sixth embodiment and the light-emitting device 5 in the fifth embodiment lies in that, the light-emitting device 6 includes several groups of second windows 120, and in each group, there are a plurality of second windows 120, each second window 120 in the group varies in horizontal-sectional area size, to enable the light-emitting structure 14 corresponding to each second window 120 to vary in light-emitting wavelength.

For example, the smaller the horizontal-sectional area of the second window 120 means that the smaller the proportion of the horizontal-sectional area of the second window 120 per unit area of the plane of the second mask layer 12, i.e., the smaller the proportion of the hole of the second window 120. The smaller the proportion of the hole of the second window 120, the faster the growth rate of the basic material GaN of the active layer 142 in the second window 120, the doping of the In element has better selectivity, and the greater the incorporation rate of the In element than the incorporation rate of the Ga element. Therefore, the smaller the proportion of the hole of the second window 120, the higher the component content of the In element in InGaN in the active layer 142, and the longer the light-emitting wavelength of the light-emitting structure 14. The larger the horizontal-sectional area of the second window 120, the lower the component content of the In element in InGaN in the active layer 142, and the shorter the light-emitting wavelength of the light-emitting structure 14.

In other embodiments, the spacing between each pair of adjacent second windows 120 in each group of the second windows 120 may also be controlled to vary, so that the light-emitting structure 14 in each second window 120 varies in light-emitting wavelength, and the principle is described below.

The greater the spacing between the adjacent second windows 120 means that the smaller the proportion of the horizontal-sectional area of the second windows 120 per unit area of the plane of the second mask layer 12, i.e., the smaller the proportion of the holes of the second windows 120, the higher the component content of In in InGaN in the active layer 142, and the longer the light-emitting wavelength of the light-emitting structure 14. The smaller the spacing between the adjacent second windows 120, the lower the component content of In in InGaN in the active layer 142, and the shorter the light-emitting wavelength of the light-emitting structure 14.

Furthermore, in some embodiments, the arrangement that each second window 120 in the group varies in horizontal-sectional area size and the arrangement that the spacing between each pair of adjacent first windows 120 varies may be used in combination.

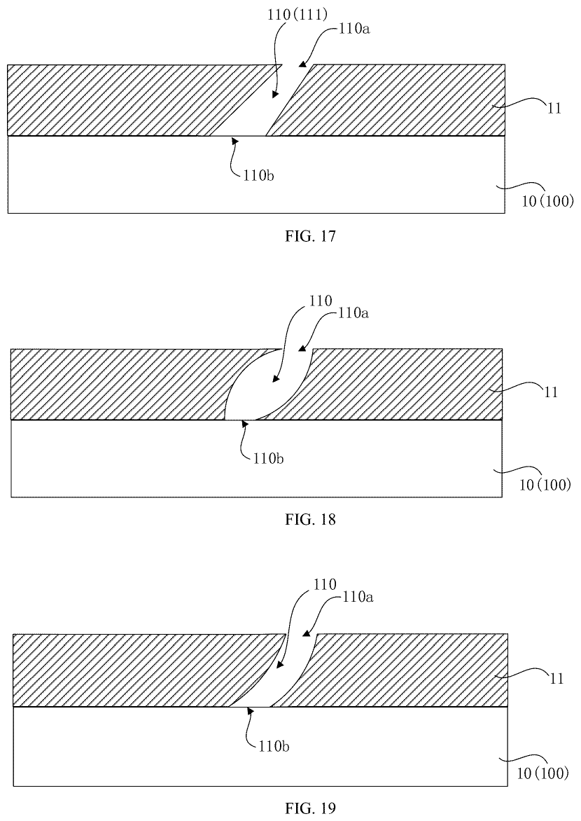

FIG. 17 is a cross-sectional structural diagram of the base and the first mask layer of the light-emitting device according to the seventh embodiment of the present disclosure.

Referring to FIG. 17, the difference between the light-emitting device and the manufacturing method thereof in the seventh embodiment, and the light-emitting devices 1, 2, 3, 4, 5, and 6 and the manufacturing methods thereof in the first to sixth embodiments lies in that, in the slanted columnar window 111, the first angle α is smaller than the supplementary angle of the second angle β.

Decreasing the first angle α can increase the area of the first sidewall 11a that terminates the dislocation extension, and thus, the dislocation termination effect of the GaN material epitaxially grown in the first window 110 is better. Furthermore, the dislocation density of the GaN material epitaxially grown in the second window 120 is lower.

FIG. 18 is a cross-sectional structural diagram of the base and the first mask layer of the light-emitting device according to the eighth embodiment of the present disclosure.

Referring to FIG. 18, the difference between the light-emitting device and the manufacturing method thereof in the eighth embodiment, and the light-emitting device and the manufacturing method thereof in the seventh embodiment lies in that, in a direction from the base 10 to the opening end 110a, the horizontal-sectional areas of the first window 110 first increase and then decrease.

The horizontal-sectional area of the first window 110 refers to the area of a section parallel to the plane of the base 10.

The area of the orthographic projection of the opening end 110a of the first window 110 on the plane of the base 10 is smaller than the area of the orthographic projection of the first window 110 on the plane of the base 10, which means that in a direction from the bottom wall end 110b toward the opening end 110a, the first window 110 has inward sidewalls. With inward sidewalls of the first window 110, the dislocations of the epitaxially grown GaN-based material may terminate on the sidewall of the first window 110 and cannot continue to extend outside the first window 110. Therefore, the base 10 having the first mask layer 11 may reduce the dislocation density of the second epitaxial layer 141. The active layer 142 and the third epitaxial layer 143 are formed by performing epitaxial growth on the second epitaxial layer 141, and therefore, the dislocation density in the active layer 142 and the third epitaxial layer 143 may also be reduced.

In addition to the above difference, other structures and process steps of the light-emitting device in the eighth embodiment may refer to the corresponding structures and process steps of the light-emitting device in the seventh embodiment.

FIG. 19 is a cross-sectional structural diagram of the base and the first mask layer of the light-emitting device according to the ninth embodiment of the present disclosure.

Referring to FIG. 19, the difference between the light-emitting device and the manufacturing method thereof in the ninth embodiment, and the light-emitting device and the manufacturing method thereof in the seventh embodiment lies in that, in a direction from the base 10 to the opening end 110a, the horizontal-sectional areas of the first window 110 are equal in size, and the line connecting the centers of the horizontal sections of the first window 110 is a curve.

In other embodiments, in a direction from the base 10 to the opening end 110a, the horizontal-sectional areas of the first window 110 may first decrease and then increase or gradually decrease; and/or the horizontal section of the first window 110 is a shape with a symmetrical center, and in a direction from the base 10 to the opening end 110a, the line connecting centers of the horizontal sections of the first window 110 is a straight line.

In addition to the above difference, other structures and process steps of the light-emitting device in the ninth embodiment may refer to the corresponding structures and process steps of the light-emitting device in the seventh embodiment.

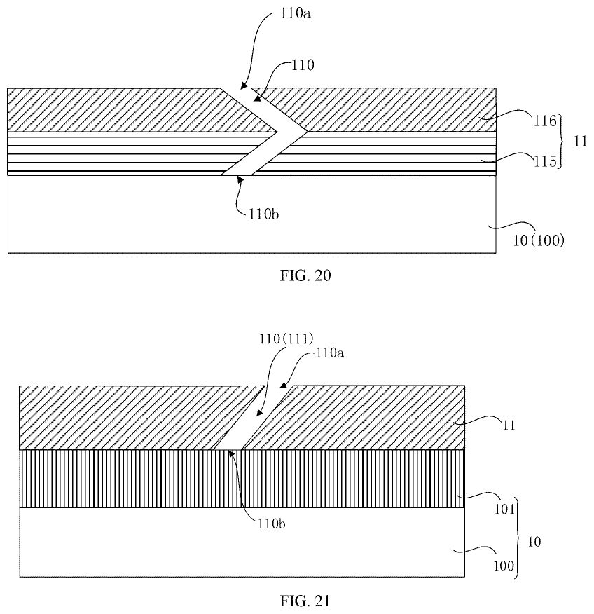

FIG. 20 is a cross-sectional structural diagram of the base and the first mask layer of the light-emitting device according to the tenth embodiment of the present disclosure.

Referring to FIG. 20, the difference between the light-emitting device and the manufacturing method thereof in the tenth embodiment, and the light-emitting device and the manufacturing method thereof in the seventh embodiment lies in that, in a direction from the base 10 to the opening end 110a, the line connecting centers of the horizontal sections of the first window 110 is a polyline. In other words, in a direction from the base 10 to the opening end 110a, the first window 110 rises in a bent shape.

In this embodiment, the first mask layer 11 may be a multi-layer structure, which includes a first thickness layer 115 close to the base 10 and a second thickness layer 116 away from the base 10, the material of the first thickness layer 115 is different from that of the second thickness layer 116, and the material of the second thickness layer 116 is different from that of the second mask layer 12. The first thickness layer 115 and the second thickness layer 116 may be formed by using a step-by-step process, and their materials are different to facilitate the formation of different sections of the first window 110 step-by-step.

In other words, in a direction from the base 10 to the opening end 110a, the first window 110 may rise in a twisted shape. Correspondingly, the multi-layer structure of the first mask layer 11 may be three or more layers, and each layer is made of a different material, to form different sections of the first window 110 step-by-step.

In addition to the above difference, other structures and process steps of the light-emitting device in the tenth embodiment may refer to the corresponding structures and process steps of the light-emitting device in the seventh embodiment.

FIG. 21 is a cross-sectional structural diagram of the base and the first mask layer of the light-emitting device according to the eleventh embodiment of the present disclosure.

Referring to FIG. 21, the difference between the light-emitting device and the manufacturing method thereof in the eleventh embodiment, and the light-emitting device and the manufacturing method thereof in the seventh embodiment lies in that, the base 10 includes a semiconductor substrate 100 and a transition layer 101 on the semiconductor substrate 100.

The transition layer 101 and the first epitaxial layer 13 may be made of the same material or different materials.

For example, the transition layer 101 may be made of GaN. Compared with the embodiment in which the transition layer 101 is omitted and the GaN material is epitaxially grown directly on a sapphire or a monocrystalline silicon semiconductor substrate 100, this embodiment may further reduce the dislocation density in the light-emitting structure 14.

In addition to the above difference, other structures and process steps of the light-emitting device in the eleventh embodiment may refer to the corresponding structures and process steps of the light-emitting device in the seventh embodiment.

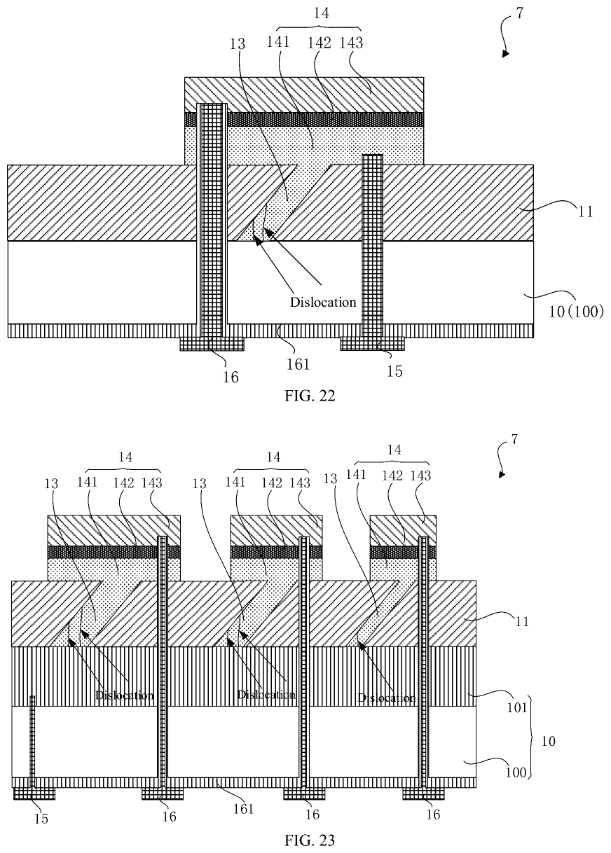

FIGS. 22 and 23 are cross-sectional structural diagrams of a light-emitting device according to the twelfth embodiment of the present disclosure.

Referring to FIG. 22, the difference between the light-emitting device 7 in the twelfth embodiment and the light-emitting devices in the first to eleventh embodiments lies in that, the light-emitting device 7 further includes:
a first electrode 15 on a side of the base 10 away from the first mask layer 11, where the first electrode 15 is electrically connected with the second epitaxial layer 141 by filling the first through hole arranged in the first mask layer 11 and the base 10; and
a second electrode 16 on a side of the base 10 away from the first mask layer 11, where the second electrode 16 is electrically connected with the third epitaxial layer 143 by filling the second through hole penetrating through the active layer 142, the second epitaxial layer 141, the first mask layer 11, and the base 10.

Since the second epitaxial layer 141 is conductive, an insulating material layer 161 may be arranged between the second electrode 16 and the sidewalls of the second through hole penetrating through the active layer 142, the second epitaxial layer 141, the first mask layer 11, and the base 10. In addition, the insulating material layer 161 may also be arranged on a side of the base 10 away from the first mask layer 11, so that the first electrode 15 and the second electrode 16 are electrically insulated from the base 10 through the insulating material layer 161.

The first electrode 15 and the second electrode 16 are not arranged on a light-emitting side of the light-emitting device 7, so that the light-emitting surface may be enlarged. In other embodiments, the first electrode 15 and the second electrode 16 may also be arranged on the light-emitting side, or the second electrode 16 may be arranged on the light-emitting side.

Referring to FIG. 23, for the light-emitting device in the eleventh embodiment, if the conductivity types of the transition layer 101 and the first epitaxial layer 13 are the same as the conductivity type of the second epitaxial layer 141, the first electrode 15 may only penetrate through the semiconductor substrate 100. Further, for the solution where the first mask layer 11 has a plurality of first windows 110, the transition layer 101 may be used as a common electrode.

The first electrode 15 and the second electrode 16 may be formed by etching through holes and then filling the through holes with metal.

In addition to the above difference, other structures and process steps of the light-emitting device in the twelfth embodiment may refer to the corresponding structures and process steps of the light-emitting devices in the first to eleventh embodiments.

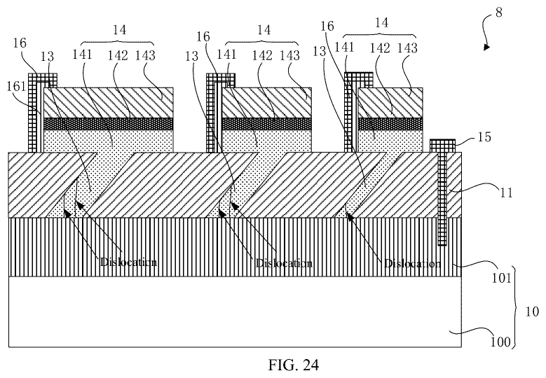

FIG. 24 is a cross-sectional structural diagram of a light-emitting device according to the thirteenth embodiment of the present disclosure.

Referring to FIG. 24, the difference between the light-emitting device 8 in the thirteenth embodiment and the light-emitting device 7 in the twelfth embodiment lies in that:
the first electrode 15 is arranged on a side of the base 10 away from the first mask layer 11, where the first electrode 15 is electrically connected with the transition layer 101 by filling the third through hole arranged in the first mask layer 11;
the insulating material 161 is arranged on the upper surface of the third epitaxial layer 143 and the side surfaces of the third epitaxial layer 143, the active layer 142, and the second epitaxial layer 141; and
the second electrode 16 is arranged on the insulating material layer 161, and the second electrode 16 is electrically connected with the third epitaxial layer 143.

The conductivity types of the transition layer 101 and the first epitaxial layer 13 are the same as the conductivity type of the second epitaxial layer 141, and the transition layer 101 may be used as a common electrode. Each second electrode 16 is connected to a drive signal.

The light-emitting device 8 in this embodiment is a top-emitting structure, i.e., the light-emitting direction is away from the base 10.

A base with a first mask layer is used as the base for epitaxial growth of the GaN-based light-emitting device, the area of an orthographic projection of the opening end on the plane of the base is smaller than the area of an orthographic projection of the first window on the plane of the base, and by utilizing inward sidewalls of the first window, the dislocation of the epitaxically grown GaN-based material terminates on the sidewalls of the first window and cannot continue to extend outside the first window. Therefore, the base with a first mask layer can reduce the dislocation density of the GaN-based materials, and improve the light-emitting efficiency of the light-emitting devices.

In addition to the above difference, other structures and process steps of the light-emitting device in the thirteenth embodiment may refer to the corresponding structures and process steps of the light-emitting devices in the first to eleventh embodiments.

It is to be noted that in the accompanying drawings, the dimensions of the layers and the regions may be exaggerated for clarity of the illustration.

In the present disclosure, terms “first” and “second” are used for descriptive purposes only and are not to be construed as indicating or implying a relative importance. The term “several” indicates one, two or more, unless explicitly defined otherwise.

Although the present disclosure discloses the above contents, the present disclosure is not limited thereto. One of ordinary skill in the art can make various changes and modifications to the present disclosure without departing from the spirit and the scope of the present disclosure. Therefore, the protection scope of the present disclosure should be set forth by the appended claims.

1. A light-emitting device, comprising:
a base;
a first mask layer on the base, wherein the first mask layer comprises a first window exposing the base, the first window comprises an opening end, and an area of an orthographic projection of the opening end on a plane of the base is smaller than an area of an orthographic projection of the first window on the plane of the base;
a first epitaxial layer, epitaxially grown from the base to fill up the first window; and
a light-emitting structure, arranged on the first epitaxial layer and the first mask layer.

2. The light-emitting device according to claim 1, wherein the light-emitting structure comprises:
a second epitaxial layer, epitaxially grown on the first epitaxial layer and the first mask layer from the first epitaxial layer;
an active layer on the second epitaxial layer; and
a third epitaxial layer on the active layer.

3. The light-emitting device according to claim 1, wherein the first mask layer is a multi-layer structure comprising alternately arranged first sublayers and second sublayers, and the first sublayers and the second sublayers have different refractive indexes to form a Bragg reflector enabling light emitted by the light-emitting structure to exit in a direction perpendicular to the plane of the base and away from the base.

4. The light-emitting device according to claim 1, wherein the first mask layer comprises a metal reflecting layer, an orthographic projection of the light-emitting structure on the plane of the base is within an orthographic projection of the metal reflecting layer on the plane of the base, and the metal reflecting layer enables light emitted by the light-emitting structure to exit in a direction perpendicular to the plane of the base and away from the base.

5. The light-emitting device according to claim 1, wherein there are groups of first windows, and in each of the groups, the group comprises a plurality of first windows, the opening end of each first window in the group varies in area size and/or spacing between opening ends of each pair of adjacent first windows in the group varies, to enable the light-emitting structure corresponding to each of the opening ends to vary in light-emitting wavelength.

6. The light-emitting device according to claim 2, further comprising:
a second mask layer on the first mask layer, wherein the second mask layer comprises a second window exposing the first mask layer, the second window is connected with the first window, and at least the second epitaxial layer and the active layer are arranged in the second window.

7. The light-emitting device according to claim 6, wherein there are groups of second windows, and in each of the groups, the group comprises a plurality of the second windows, each second window in each of the groups varies in horizontal sectional area size and/or spacing between each pair of adjacent second windows in each of the groups varies, to enable the light-emitting structure corresponding to each of the plurality of second windows to vary in light-emitting wavelength.

8. The light-emitting device according to claim 7, wherein a composition of the active layer is InGaN, and in each of the groups, each of the plurality of second windows varies in horizontal-sectional area size and/or the spacing between each pair of adjacent second windows of the plurality of second windows varies, to enable a component content of In in a corresponding InGaN in the plurality of second windows to vary.

9. The light-emitting device according to claim 1, wherein the first window further comprises a bottom wall end on a surface of the base, and the orthographic projection of the opening end on the plane of the base is at least partially staggered from the bottom wall end.

10. The light-emitting device according to claim 9, wherein the orthographic projection of the opening end on the plane of the base is completely outside from the bottom wall end.

11. The light-emitting device according to claim 1, wherein the first window is a slanted columnar window.

12. The light-emitting device according to claim 1, wherein in a direction from the base to the opening end, horizontal-sectional areas of the first window first increase and then decrease; in a direction from the base to the opening end, the horizontal-sectional areas of the first window gradually decrease; or in a direction from the base to the opening end, the horizontal-sectional areas of the first window are equal in size.

13. The light-emitting device according to claim 1, wherein in a direction from the base to the opening end, a line connecting centers of horizontal sections of the first window is a straight line, a polyline, or a curve.

14. A manufacturing method of a light-emitting device, comprising:
providing a base, forming a first mask layer on the base (10), and in the first mask layer, forming a first window exposing the base, wherein the first window comprises an opening end, to enable an area of an orthographic projection of the opening end on a plane of the base to be smaller than an area of an orthographic projection of the first window on the plane of the base; and
performing an epitaxial growth process on the base to sequentially form a first epitaxial layer and a light-emitting structure by using the first mask layer as a mask, wherein the first epitaxial layer is epitaxially grown from the base to fill up the first window, and the light-emitting structure is epitaxially grown on the first epitaxial layer and the first mask layer.

15. The manufacturing method according to claim 14, wherein the light-emitting structure comprises:
a second epitaxial layer, epitaxially grown on the first epitaxial layer and the first mask layer from the first epitaxial layer;
an active layer on the second epitaxial layer; and
a third epitaxial layer on the active layer.

16. The manufacturing method according to claim 14, wherein the first mask layer is formed by:
alternately depositing first sublayers and second sublayers to form a multi-layer structure;
or
depositing a first mask sublayer;
forming a metal reflecting layer on the first mask sublayer, to enable an orthographic projection of a predetermined region of the light-emitting structure on the plane of the base to fall within an orthographic projection of the metal reflecting layer on the plane of the base; and
forming a second mask sublayer on the metal reflecting layer and the first mask sublayer, wherein the first mask layer is formed by the first mask sublayer and the second mask sublayer.

17. The manufacturing method according to claim 15, wherein before the step of forming the first epitaxial layer and the light-emitting structure, the manufacturing method of the light-emitting device further comprises:
forming a second mask layer on the first mask layer, and in the second mask layer, forming a second window exposing the first mask layer, wherein the second window is connected with the first window; and
performing an epitaxial growth process on the base by using the first mask layer and the second mask layer as a mask, wherein at least the second epitaxial layer and the active layer of the light-emitting structure are epitaxially grown in the second window.

18. The manufacturing method according to claim 17, wherein a composition of the active layer is InGaN, there are groups of second windows, and in each of the groups, the group comprises a plurality of second windows, each of the plurality of second windows varies in horizontal-sectional area size and/or spacing between each pair of adjacent second windows of the plurality of second windows varies, to enable a component content of In in a corresponding InGaN epitaxially grown in the second window to vary.

19. The manufacturing method according to claim 14, wherein in a direction from the base to the opening end, horizontal-sectional areas of the first window first increase and then decrease; in a direction from the base to the opening end, the horizontal-sectional areas of the first window gradually decrease; or in a direction from the base to the opening end, the horizontal-sectional areas of the first window are equal in size.

20. The manufacturing method according to claim 14, wherein in a direction from the base to the opening end, a line connecting centers of horizontal sections of the first window is a straight line, a polyline, or a curve.
